(19) United States
(12) Patent Application Publication
(10) Pub. No.: US 2004/0182816 A1
(43) Pub. Date: Sep. 23, 2004

(54) Thin flat panel display and method for manufacturing the same

(75) Inventors: Ho-Kyoon Chung, Yongin-city (KR); Jin-Woo Park, Yongin-city (KR); Seung-Yong Song, Kyungki-do (KR)

Correspondence Address: McGuire Woods LLP, Suite 1800, 1750 Tysons Boulevard, McLean, VA, 22102, US

(73) Assignee: Samsung SDI Co., Ltd.

(21) Appl. No.: 10/728,787

(22) Filed: Dec. 8, 2003

(30) Foreign Application Priority Data
Mar. 18, 2003 (KR) 2003-0016842

(51) Int. Cl. C30B 33/00

(52) U.S. Cl. 216/23

(57) ABSTRACT

A thin flat panel display which can be simply manufactured, and a method for manufacturing the same. An etchable upper substrate and an etchable lower substrate are prepared. Image display means are formed on an inner surface of the lower substrate in such a way that if two or more image display means are provided, each of the image display means are isolated from each other. The upper and lower substrates are combined together so that the image display means are individually sealed up. The outer surfaces of the upper and lower substrates are etched. The combined upper and lower substrates are cut in units of an image display means.

### CROSS REFERENCE

This application claims the priority of Korean Patent Application No. 2003-16842, filed on Mar. 18, 2003, in the Korean Intellectual Property Office, the disclosure of which is incorporated herein by reference in its entirety.

### BACKGROUND OF THE INVENTION

1. Field of the Invention

The invention relates to a thin flat panel display and a method of manufacturing the same, and more particularly, to flexible flat panel displays.

2. Description of the Related Art

A substrate used in flexible flat panel displays must be flexible. A synthetic resin substrate is generally used as such a flexible substrate. However, such a synthetic resin substrate requires very complicated manufacturing conditions in order to form an electrode layer, an organic layer, a thin film transistor layer, and an orientation layer, and the like thereon. If the conditions are not satisfied, the synthetic resin substrate or the layers formed thereon are deformed.

A method of manufacturing an image display device using a damp-proof substrate in consideration of this problem is disclosed in Japanese Patent Publication No. 2000-123971. JP 2000-123971 discloses a method of manufacturing an organic electro-luminescent (EL) display device. In the disclosed organic EL display device, at least one of two insulative substrates is flexible, and at least one of the two insulative substrates is permeable to light. An electrode layer is formed on each of the inner surfaces of the two substrates, and a luminescent layer is placed between the two electrode layers. The method of manufacturing the disclosed organic EL display device includes the steps of depositing an electrode layer and a luminescent layer on one substrate, depositing another electrode layer or the like on the other substrate, and closely adhering the two substrates to each other.

### SUMMARY OF THE INVENTION

The invention provides a thin flat panel display which can be simply manufactured, and a method of manufacturing the same.

The invention separately provides a method for manufacturing a thin flat panel display. An etchable upper substrate and an etchable lower substrate are prepared. At least two image display means are formed on an inner surface of the lower substrate in such a way that the at least two image display means are isolated from each other. The upper and lower substrates are combined together so that the image display means are individually sealed up. The outer surfaces of the upper and lower substrates are etched. The combined upper and lower substrates are cut such that each image display means is separate.

The invention, separately provides another method for manufacturing a thin flat panel display. An etchable upper substrate and an etchable lower substrate are prepared for. One image display means is formed on an inner surface of the lower substrate. The upper and lower substrates are combined together so that the image display means is sealed up. The outer surfaces of the upper and lower substrates are etched.

In various embodiments of the invention, the upper and lower substrates are formed of a glass-based material.

In various embodiments of the invention, after the upper and lower substrates are combined together, an unetchable protection film is attached to the lateral sides of the combined upper and lower substrates.

In various embodiments of the invention, in the etching step, the outer surfaces of the upper and lower substrates are etched so that the upper and lower substrates have a total thickness of 0.5 mm or smaller.

In various embodiments of the invention, there is provided a thin flat panel display which includes an upper substrate, a lower substrate, an image display means, and a protection film. The upper and lower substrates are etched to have a thickness of 0.5 mm or smaller and combined together. The image display means is formed on an inner surface of the lower substrate. The protection film is attached to the lateral sides of the combined upper and lower substrates.

In various embodiments of the invention, the image display means includes a first electrode layer, a luminescent layer formed on the first electrode layer, and a second electrode layer formed on the luminescent layer.

In various embodiments thin upper and lower substrates can be obtained while still employing a conventional method of manufacturing a flat panel display. Also, because an image display means is provided while the upper and lower substrates are still thick, the stability of the manufacturing process and the nondefective proportion of products are improved.

### BRIEF DESCRIPTION OF THE DRAWINGS

The above and other features and advantages of the invention will become more apparent by the following detailed description of exemplary embodiments thereof with reference to the attached drawings:

FIG. 1 is a cross-sectional view showing a thin flat panel display after a first step of a method for manufacturing a thin flat panel display according to the invention.

FIG. 2A is a cross-sectional view showing a thin flat panel display having a thin film transistor during a second step of the method for manufacturing a thin flat panel display according to the invention.

FIG. 2B is a cross-sectional view showing a thin flat panel display having first and second electrode layers and a luminescent layer, which are connected to the thin film transistor, during the second step of the method for manufacturing a thin flat panel display according to the invention.

FIG. 2C is a cross-sectional view showing a thin flat panel display after a second step of the method for manufacturing a thin flat panel display according to the invention.

FIG. 3A is a cross-sectional view showing upper and lower substrates joined together during a third step of the method for manufacturing a thin flat panel display according to the invention.

FIG. 3B is a cross-sectional view showing the joined upper and lower substrates having a protection film attached to their side edges in the third step of the method for manufacturing a thin flat panel display according to the invention.

FIG. 4 is a cross-sectional view illustrating a fourth step of the method for manufacturing a thin flat panel display according to the invention.

FIG. 5 is a cross-sectional view illustrating a fifth step of the method for manufacturing a thin flat panel display according to the invention.

### DETAILED DESCRIPTION OF THE INVENTION

A method for manufacturing a thin flat panel display according to the invention can be applied to image display devices, such as, organic EL displays, and the like. The method for manufacturing a thin flat panel display does not affect a process of forming an image display means (e.g., an electrode layer, an organic layer, a thin film transistor layer, an orientation layer, and the like). A thin flat panel display according to the invention has flexible substrates.

FIG. 1 shows etchable upper and lower substrates 12 and 11 prepared during a first step in a method for manufacturing a thin flat panel display according to an exemplary embodiment of the invention. The upper and lower substrates 12 and 11 in the first step are thicker than those of a completed thin flat panel display, and accordingly, they have sufficient structural strength. Hence, when an image display part to be described later is formed, pattern distortion is prevented. In the embodiment of FIG. 1, the upper and lower substrates 12 and 11 are formed of an etchable glass-based material. However, the invention is not limited to this embodiment, so the upper and lower substrates 12 and 11 may be formed of other materials that are etchable and have an insulating property. The upper and lower substrates 12 and 11 have inner surfaces 12a and 11a, respectively.

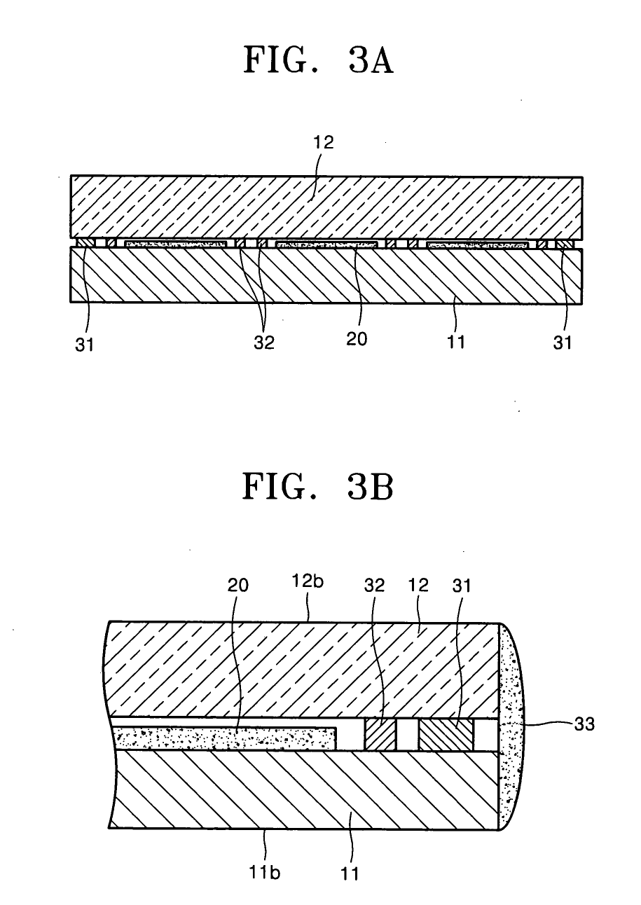

After the upper and lower substrates 12 and 11 are completely prepared, a second step of forming an image display means 20 on the inner surface 11a of the lower substrate 11 is executed (see FIG. 3A). Depending on the size of the to-be-manufactured thin flat panel display and the conditions for manufacturing the same, one or a plurality of image display means 20 is formed on the inner surface (i.e., the upper surface) 11a of the lower substrate 11. If a plurality of image display means are formed on the upper surface 11a of the lower substrate 11, the upper and lower substrates 12 and 11 are cut in units of image display means in a fifth step to be described later. Thus, different image display means are isolated from one another at predetermined intervals. If a large-sized flat panel display is intended to be manufactured, one large image display means can be formed on the lower substrate 11.

The detailed structure of the image display means varies depending on the type of a thin flat panel display to be manufactured. In the specification, an organic EL display device is chosen as an example of the thin flat panel display.

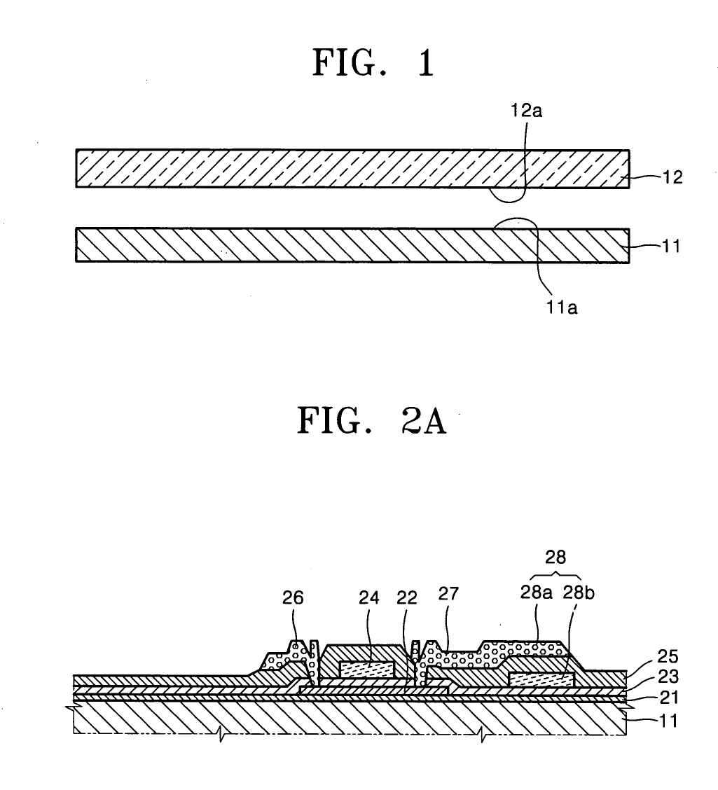

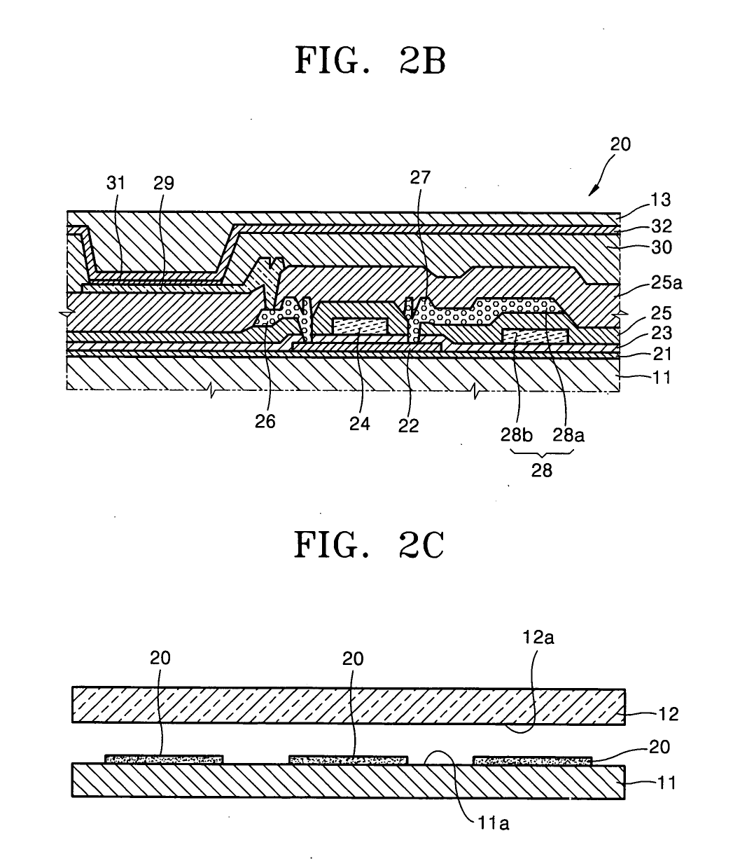

FIG. 2A shows the lower substrate 11 having a thin film transistor of the organic EL display device. As shown in FIG. 2A, a buffer layer 21 is formed on the upper surface of the lower substrate 11. P-type and/or n-type semiconductor layers 22 are formed on the buffer layer 21 in a predetermined pattern. The p-type or n-type semiconductor layers 22 are covered with a gate insulating layer 23. A gate electrode layer 24, which can form a conductive channel in the semiconductor layer 22, is formed on the upper surface of the gate insulating layer 23 and covered with a first insulating layer 25. The first insulating layer 25 and the gate insulating layer 23 have holes that expose some areas of the semiconductor layer 22. The holes are filled with a drain electrode 26 and a source electrode 27, and the first insulating layer 25 is covered therewith. Each of the drain and source electrodes 26 and 27 is electrically connected to the semiconductor layer 22. A capacitor 28 is located beside the thin film transistor and includes a first electrode 28b and a second electrode 28a. The first electrode 28b is formed at the same time when the gate electrode 24 is formed. The second electrode 28a is formed simultaneously with the formation of the source electrode 27 so as to be combined therewith.

FIG. 2B shows the lower substrate 11 having a sub-pixel, which includes a luminescent layer 31 and two electrode layers 32 and 29. The luminescent layer 31 emits light, and the two electrode layers 32 and 29 are formed on upper and lower surfaces, respectively, of the luminescent layer 31. After the thin film transistor is formed on the lower substrate 11 as shown in FIG. 2A, a second insulating layer 25a is formed on the upper surface of the first insulating layer 25. A first electrode layer 29 electrically connected to the drain electrode 26 is formed on the upper surface of the second insulating layer 25a. A third insulating layer 30 is formed on the upper surface of the second insulating layer 25a. The luminescent layer 31 is formed on the upper surface of the first electrode layer 29. A second electrode layer 32 is formed on the upper surface of the luminescent layer 31 and on the upper surface of the third insulating layer 30. A protection film 13 is formed on the second electrode layer 32 in order to level a resultant uneven surface of the second electrode layer 32. FIG. 2B shows one sub-pixel. Such sub-pixels are arranged in a matrix configuration on the lower substrate 11, thereby forming one image display means 20.

If the image display means is to be manufactured using liquid crystal, the second electrode layer 32 is formed on the lower surface of the upper substrate 12. An orientation layer for orienting liquid crystal is formed on each of facing surfaces of the first and second electrode layers 29 and 32. The space between the two orientation layers is filled with liquid crystal.

After the second step is completed, the upper and lower substrates 12 and 11 have cross-sections as shown in FIG. 2C.

A third step of combining the upper and lower substrates 12 and 11 together so that the image display means 20 are individually sealed up will now be described with reference to FIG. 3A. In the third step, a first sealing member 31 is formed on the facing edges of the upper and lower substrates 12 and 11, and a second sealing member 32 is formed such as to partition each of the image display means 20. After the first and second sealing members 31 and 32 are coated, the upper and lower substrates 12 and 11 are aligned and then combined together. The first sealing member 31 formed on the facing edges of the upper and lower substrates 12 and 11 protects the image display means 20 from an etching solution, which is used in a fourth step to be described later. In the third step, preferably, an unetchable protection film 33 is attached to the lateral sides of the upper and lower substrates 12 and 11 as shown in FIG. 3B in order to prevent the sides of the upper and lower substrates 12 and 111 from being etched by an etching solution.

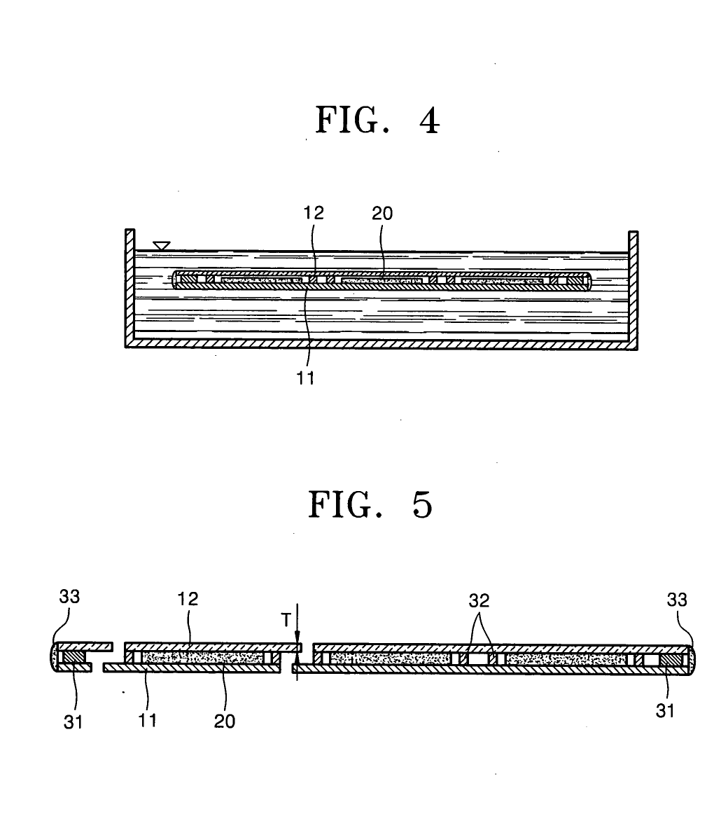

After the third step of combining the upper and lower substrates 12 and 11, a fourth step of etching outer surfaces 12b and 11b (shown in FIG. 3) of the upper and lower substrates 12 and 11, respectively, is performed, as shown in FIG. 4. Although FIG. 4 shows chemical etching of the outer surfaces 12b and 11b of the upper and lower substrates 12 and 11, it may be etched in a physical method. An etching solution for the chemical etching may be fluoric acid, hydrochloric acid, or the like. Preferably, the thickness (T) of each of final upper and lower substrates etched is smaller than or equal to 0.5 mm. If the thickness (T) of each of the final upper and lower substrates is less than or equal to 100 μm, the final upper and lower substrates become flexible. The thicknesses of the upper and lower substrates may be determined differently from the beginning in order to obtain final upper and lower substrates of different thicknesses.

FIG. 5 illustrates a fifth step of cutting the upper and lower substrates 12 and 11 whose outer surfaces 12b and 11b have been etched in the fourth step, in units of an image display means 20. The fifth step is required in the case that a plurality of image display means are formed on a lower substrate. Preferably, the upper and lower substrates 12 and 111 are cut apart using a laser beam.

In the above-described method for manufacturing a thin flat panel display, the image display means 20 are formed on the lower substrate 11 according to a method for manufacturing a non-thin-type flat panel display, the lower substrate 11 having the image display means 20 is combined with the upper substrate 12, and the outer surfaces 12b and 111b thereof are etched, thereby manufacturing a thin flat panel display. Hence, the manufacturing process is simple, and the number of inferior goods produced due to the formation of an image display means on a thin substrate can be greatly reduced.

The operation of an organic EL display manufactured in such a manufacturing method according to the invention will now be described briefly. When a predetermined voltage is applied to the first and second electrode layers 29 and 32 by a thin film transistor, holes introduced from the first electrode layer 29 are combined with electrons introduced from the second electrode layer 32 in the luminescent layer 31 to thereby produce exitons. As the excited state of the excitons is changed to a ground state, fluorescent molecules on the luminescent layer 31 emit light. The emitted light is discharged from the organic EL display device via the first or second electrode layer 29 or 32.

In such thin flat panel displays, after the upper and lower substrates are adhered to each other, their outer surfaces are etched, and accordingly they become thinner. Hence, the upper and lower substrates become flexible.

In a method for manufacturing a thin flat panel display according to the invention, thin upper and lower substrates can be obtained even by using a conventional method for manufacturing a non-thin flat panel display. Also, because an image display means is formed when the upper and lower substrates are still thick, the stability of the manufacturing process and the nondefective proportion of products are improved.

While the invention has been particularly shown and described with reference to exemplary embodiments thereof, it will be understood by those of ordinary skill in the art that various changes in form and details may be made therein without departing from the spirit and scope of the invention as defined by the following claims. For example, the invention can be applied to liquid crystal displays and the like.

What is claimed is:

1. A method for manufacturing a thin flat panel display, the method comprising:
preparing an etchable upper substrate and an etchable lower substrate;
forming image display means on an inner surface of the lower substrate in such a way that the at least two image display means are isolated from each other;
combining the upper substrate and the lower substrate together so that the image display means are individually sealed up;
etching outer surfaces of the upper substrate and the lower substrate; and
cutting the combined upper and lower substrates in units of an image display means such that each image display means is separate.

2. The method of claim 1, wherein the upper and lower substrates are formed of a glass-based material.

3. The method of claim 1, wherein the combining step comprises attaching an unetchable protection film to each lateral side of the combined upper and lower substrates.

4. The method of claim 1, wherein during the etching step, the outer surfaces of the upper and lower substrates are etched so that the upper substrate and the lower substrate have a total thickness of at most 0.5 mm.

5. A method for manufacturing a thin flat panel display, the method comprising:
preparing for an etchable upper substrate and an etchable lower substrate;
forming an image display means on an inner surface of the lower substrate;
combining the upper substrate and the lower substrate together so that the image display means is sealed up; and
etching the outer surfaces of the upper substrate and the lower substrate.

6. The method of claim 5, wherein the upper substrate and the lower substrate are formed of a glass-based material.

7. The method of claim 5, wherein the combining step comprises attaching an unetchable protection film to each lateral side of the combined upper and lower substrates.

8. The method of claim 5, wherein during the etching step, the outer surfaces of the upper substrate and the lower substrate are etched so that the upper and lower substrates have a total thickness of at most 0.5 mm.

9. A thin flat panel display comprising:
an upper substrate and a lower substrate which are etched to have a thickness of 0.5 mm or smaller and combined together;
an image display means formed on an inner surface of the lower substrate; and
a protection film attached to the lateral sides of the combined upper and lower substrates.

10. The thin flat panel display of claim 9, wherein the image display means comprises:
a first electrode layer;
a luminescent layer formed on the first electrode layer; and
a second electrode layer formed on the luminescent layer.
